(19) United States
(12) Patent Application Publication
(10) Pub. No.: US 2025/0263833 A1
(43) Pub. Date: Aug. 21, 2025

(54) METHOD AND SYSTEM FOR DEPOSITING A METAL-CONTAINING LAYER

(71) Applicant: ASM IP Holding B.V., Almere (NL)

(72) Inventors: Timo Hatanpää, Espoo (FI); Anton Vihervaara, Helsinki (FI); Mikko Ritala, Helsinki (FI)

(21) Appl. No.: 19/051,248

(22) Filed: Feb. 12, 2025

Related U.S. Application Data
(60) Provisional application No. 63/553,686, filed on Feb. 15, 2024.
(60) Provisional application No. 63/673,218, filed on Jul. 19, 2024.

(51) Int. Cl. C23C 16/18; C23C 16/04; C23C 16/455; H01L 21/285

(52) U.S. Cl. CPC C23C 16/18; C23C 16/04; C23C 16/45553; H01L 21/28556

(57) ABSTRACT

The present disclosure relates to methods and apparatuses for depositing metal-containing material on a substrate by a cyclic deposition process. The method comprises providing a substrate in a reaction chamber, providing a metal alkoxide precursor into the reaction chamber in a vapor phase; and providing a second precursor into the reaction chamber in a vapor phase to form metal-containing material on the substrate. The second precursor comprises a borane compound.

### CROSS-REFERENCE TO RELATED APPLICATIONS

This application claims priority to and benefit of U.S. Provisional Application No. 63/553,686, filed Feb. 15, 2024, and U.S. Provisional Application No. 63/673,218, filed Jul. 19, 2024, the entirety of each application is incorporated by reference herein.

### PARTIES OF JOINT RESEARCH AGREEMENT

The invention claimed herein was made by, or on behalf of, and/or in connection with a joint research agreement between University of Helsinki and ASM Microchemistry Oy. The agreement was in effect on and before the date the claimed invention was made, and the claimed invention was made as a result of activities undertaken within the scope of the agreement.

### FIELD OF INVENTION

The present disclosure relates to methods and apparatuses for the manufacture of semiconductor devices. More particularly, the disclosure relates to methods and apparatuses for depositing metal-containing material on a substrate by a cyclical deposition process, and layers comprising metal-containing material.

### BACKGROUND OF THE DISCLOSURE

Copper is the most used interconnect material in microelectronics. Although there is a push to switch into other metals, copper will remain an important metal for interconnects for the immediate future. Modern applications require high-quality thin films deposited uniformly over large areas and on 3D structures. To achieve these films, gas phase thin film deposition methods are required and out of these the method that can best meet the demands is atomic layer deposition (ALD).

There are several existing processes for depositing copper with ALD, but many of them require high temperatures. In the case of metals, high deposition temperatures typically lead to increased agglomeration of the films during growth. This means that the critical thickness (thickness at which the metal islands coalescence into a continuous film) is greater than it would be with lower deposition temperatures. Low temperature thermal ALD processes can be achieved with smart chemistry.

Other metals, such as metallic bismuth, on the other hand, do not have such an important role in current microelectronics. However, this does not mean that they are not interesting materials, as many of them possess unique characteristics that could be exploited in the future. Possible applications suggested in the literature include semiconductor devices, superconductors, and anodes for batteries. For example, bismuth (Bi) undergoes semimetal-semiconductor (SMSC) transition, which is unique and has an interesting effect. Furthermore, many other important materials include bismuth as a component, such as bismuth chalcogenides. Bismuth is a heavy element and therefore Bi films may find application in e.g., x-ray optics and various novel patterning methods (EUV, multiple patterning).

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

Various embodiments of the present disclosure relate to methods of depositing metal-containing material on a substrate, to a metal-containing layer, to a semiconductor structure and a device containing said layer, and to deposition assemblies for depositing metal-containing material on a substrate.

In a first aspect, a method of depositing a material on a substrate by a cyclic deposition process is disclosed. The method comprises providing a substrate into a reaction chamber; providing a metal alkoxide precursor into the reaction chamber in vapor phase; and providing a second precursor into the reaction chamber in vapor phase to form a material on the substrate. In the method, the second precursor comprises a borane compound.

In some embodiments, the metal alkoxide precursor is provided into the reaction chamber at a deposition temperature of 80-130° C., or 200-300° C., or 80-250° C.

In some embodiments, the metal alkoxide precursor comprises at least one alkoxide ligand.

In some embodiments, wherein the metal alkoxide precursor comprises at least two alkoxide ligands.

In some embodiments, the metal alkoxide precursor comprises three alkoxide ligands.

In some embodiments, the metal alkoxide precursor is a metal aminoalkoxide precursor.

In some embodiments, the metal alkoxide precursor comprises a ligand selected from the group consisting of 1-dimethylamino-2-propoxide (dmap), 1-dimethylamino-2-methyl-2-propoxide (dmamp), 1-ethylmethylamino-2-methyl-2-propoxide (emamp), 1-diethylamino-2-methyl-2-propoxide (deamp), 1-ethylmethylamino-2-methyl-2-butoxide (emamb), 1-dimethylamino-2-methyl-2-butoxide (deamb) and 1-dimethylamino-2-ethyl-2-butoxide (dmaeb).

In some embodiments, the metal atom of the metal alkoxide precursor is selected from the group consisting of late transition metals and post-transition metals.

In some embodiments, the metal atom is selected from the group consisting of Ni, Cu, Co, Zn, Fe, Al, Bi, Ga, In, Tl, Sn and Pb.

In some embodiments, the metal atom comprises Bi or Cu.

In some embodiments, the metal alkoxide precursor is selected from the group consisting of Ni(dmap)₂, Ni(dmamp)₂, Ni(emamp)₂, Ni(deamp)₂, Ni(emamb)₂, Ni(deamb)₂, Ni(dmaeb)₂, Co(dmap)₂, Co(dmamp)₂, Co(emamp)₂, Co(deamp)₂, Co(emamb)₂, Co(deamb)₂, Co(dmaeb)₂, Cu(dmap)₂, Cu(dmamp)₂, Cu(emamp)₂, Cu(deamp)₂, Cu(emamb)₂, Cu(deamb)₂, Cu(dmaeb)₂, Fe(dmap)₂, Fe(dmamp)₂, Fe(emamp)₂, Fe(deamp)₂, Fe(emamb)₂, Fe(deamb)₂, Fe(dmaeb)₂, Zn(dmap)₂, Zn(dmamp)₂, Zn(emamp)₂, Zn(deamp)₂, Zn(emamb)₂, Zn(deamb)₂, Zn(dmaeb)₂, Al(OⁱPr)₃, Al(OBu)₃, Al(OEt)₃, AlOⁱPr(Me)₂, Bi(OCMe₂ⁱPr)₃, Ga(O^{t}Bu)₃, GaCl₂(OCH₂CH₂NMe₂), Cu(OMe)₂, Cu(dmap)₂, Pb(dmamp)₂, Tl(OEt), Sn(O^{t}Bu)₄, Sn(OEt), Zn(OⁱPr)₂, Mo(thd), Nb(OEt) 5 and MO₂(O₂CCH₃)₄

In some embodiments, the metal alkoxide precursor is selected from the group consisting of Al(OⁱPr)₃, Al(OBu)₃, Al(OEt)₃, AlOⁱPr(Me)₂, Bi(OCMe₂ⁱPr)₃, Ga(O^{t}Bu)₃, GaCl₂(OCH₂CH₂NMe₂), In(O^{t}Bu)₃, Cu(OMe)₂, Cu(dmap)₂, Pb(dmamp)₂, Tl(OEt), Sn(O^{t}Bu)₄, Sn(OEt)₂and Zn(OⁱPr)₂.

In some embodiments, the metal alkoxide precursor is selected from the group consisting of Bi(OCMe2iPr)₃ and Cu(dmap)2.

In some embodiments, the second precursor is a reducing agent.

In some embodiments, the second precursor is selected from the group consisting of pinacolborane, bis-pinacolatoboron, 9-BBN, Borane morpholine, catechol borane, 2-picoline borane, borane pyridine adduct, decaborane, 1,4-bis(pinacolatoboron)-1,4-dihydropyrazine, H₃B*NEt₃, H₃B*NHMe₂, H₃B*SMe₂, BN(Et)ⁱPr₂ and BH₃*THF.

In some embodiments, the second precursor comprises an alkoxy borane compound.

In some embodiments, the second precursor comprises pinacolborane.

In some embodiments, the second precursor comprises 1,4-bis(pinacolatoboron)-1,4-dihydropyrazine.

In some embodiments, the metal-containing material comprises elemental metal.

In a second aspect, a metal-containing layer produced by a cyclic deposition process is disclosed. The process comprises providing a substrate into a reaction chamber; providing a metal alkoxide precursor into the reaction chamber in vapor phase; and providing a second precursor into the reaction chamber in vapor phase to form a material on the substrate. In the process, the second precursor comprises a borane compound.

In a third aspect, a semiconductor structure comprising a metal-containing layer deposited by a cyclic deposition process is disclosed. The process comprises providing a substrate into a reaction chamber; providing a metal alkoxide precursor into the reaction chamber in vapor phase; and providing a second precursor into the reaction chamber in vapor phase to form a material on the substrate. In the process, the second precursor comprises a borane compound.

In a fourth aspect, a semiconductor device comprising a metal-containing layer deposited by a cyclic deposition process is disclosed. The process comprises providing a substrate into a reaction chamber; providing a metal alkoxide precursor into the reaction chamber in vapor phase; and providing a second precursor into the reaction chamber in vapor phase to form material on the substrate. In the process, the second precursor comprises a borane compound.

In a fifth aspect, a deposition assembly for depositing metal-containing material on a substrate is disclosed. The deposition assembly comprises one or more reaction chambers constructed and arranged to hold the substrate; a precursor injector system constructed and arranged to provide a metal alkoxide precursor and a second precursor into the reaction chamber in a vapor phase. The second precursor comprises a borane compound. The deposition assembly further comprises a precursor vessel constructed and arranged to contain a metal alkoxide precursor; and the assembly is constructed and arranged to provide the metal alkoxide precursor and the second precursor via the precursor injector system to the reaction chamber to deposit metal-containing material on the substrate.

In a sixth aspect, a vessel comprising a chemical precursor is disclosed. The vessel comprises bismuth alkoxide, wherein the vessel is configured to supply a vapor of the chemical precursor to a semiconductor processing apparatus chamber.

In a seventh aspect, a metal-containing film deposition product is disclosed. The product comprises: a metal-containing chemical precursor comprising metal alkoxide; a second precursor comprising alkoxy borane; a first vessel comprising the chemical precursor; and a second vessel comprising the second precursor, wherein the metal-containing chemical precursor is provided in the first vessel and the second precursor is provided in the second vessel, wherein the first and second vessels are configured to couple to a semiconductor apparatus via a reactant delivery system.

In an eighth aspect, a selective deposition method is disclosed. The method comprises providing a substrate into a reaction chamber; providing a metal alkoxide precursor into the reaction chamber in vapor phase; and providing a second precursor into the reaction chamber in vapor phase to form a material on the substrate. In the method, the second precursor comprises a borane compound. The substrate comprises a first surface and a second surface. The deposited material is formed more on the first surface compared to the second surface.

### BRIEF DESCRIPTION OF THE DRAWING FIGURES

The accompanying drawings, which are included to provide a further understanding of the disclosure and constitute a part of this specification, illustrate exemplary embodiments, and together with the description help to explain the principles of the disclosure. In the drawings:

FIGS. 1A and 1B illustrate a block diagram of embodiments of a method according to the current disclosure.

FIG. 2 is a schematic presentation of a deposition assembly according to the current disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention, and obvious modifications and equivalents thereof. Thus, it is intended that the scope of the invention disclosed should not be limited by the particular disclosed embodiments described below.

In one aspect, a method of deposition a material on a substrate by cyclic deposition process is disclosed. The method comprises providing a substrate into a reaction chamber; providing a metal alkoxide precursor into the reaction chamber in vapor phase; and providing a second precursor into the reaction chamber in vapor phase to form a material on the substrate. In the method, the second precursor comprises a borane compound.

In cyclic deposition processes, the phases of providing the metal alkoxide precursor and providing the second precursor into the reaction chamber are repeated until a desired material thickness is achieved.

In the methods according to the current disclosure, the material deposited on a substrate comprises a metal. In some embodiments, the metal-containing material comprises transition metal. In some embodiments, the metal-containing material comprises late transition metal. Late transition metal is defined as group 8 to 12metals. In some embodiments, the metal-containing material comprises post-transition metal. Post-transition metal is defined as the group of metals which consists of aluminum, gallium, indium, thallium, tin, lead, bismuth, germanium, antimony and polonium. In some embodiments, the metal-containing material comprises copper. In some embodiments, the metal-containing material comprises bismuth. In some embodiments, the metal-containing material comprises elemental metal.

In some embodiments, the metal-containing material comprises a metal oxide. In some embodiments, the metal-containing material comprises a metal nitride. In some embodiments, the metal-containing material comprises a metal carbide. In some embodiments, the metal-containing material comprises a metal selenide. In some embodiments, the metal-containing material comprises a metal sulfide. In some embodiments, the metal-containing material comprises a metal phosphide. In some embodiments, the metal-containing material comprises a metal boride. In some embodiments, the metal-containing material comprises a metal germanide.

As used herein, the term “layer” and/or “film” can refer to any continuous or noncontinuous structure and material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. A seed layer may be a noncontinuous layer serving to increase the rate of nucleation of another material. However, the seed layer may also be substantially or completely continuous. A layer of desired thickness may be deposited by repeating sufficiently providing a metal alkoxide precursor and a second precursor in the reaction chamber multiple times. A layer produced according to the methods disclosed herein may form a part of a semiconductor structure and/or a semiconductor device.

In a further aspect, a semiconductor structure comprising a metal-containing layer deposited by a cyclic deposition process is disclosed. The cyclic deposition process is performed as described herein, and the process is integrated with additional processing steps to produce the semiconductor structure. The semiconductor structure may be a part of a semiconductor device. Such devices are used in the manufacture of integrated circuits.

In some embodiments, the metal-containing material is deposited as a layer on a substrate. In some embodiments, the metal-containing layer comprises elemental metal. The thickness of a metal-containing material layer may be regulated by adjusting the cycle number of the cyclic deposition process. In some embodiments, the cyclic deposition process comprises providing the metal alkoxide precursor and the second precursor alternately and sequentially into the reaction chamber. In some embodiments, the reaction chamber is purged between providing precursors into the reaction chamber. Examples of such cyclic deposition processes are atomic layer deposition and cyclic chemical vapor deposition.

As used herein, the term “substrate” may refer to any underlying material or materials that may be used to form, or upon which, a device, a circuit, material or a material layer may be formed. A substrate can include a bulk material, such as silicon (such as single-crystal silicon), other Group IV materials, such as germanium, or other semiconductor materials, such as a Group II-VI or Group III-V semiconductor materials. A substrate can include one or more layers overlying the bulk material. The substrate can include various topologies, such as gaps, including recesses, lines, trenches or spaces between elevated portions, such as fins, and the like formed within or on at least a portion of a layer of the substrate. The substrate may include nitrides, for example, TiN, oxides, insulating materials, dielectric materials, conductive materials, metals, such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers.

In the current disclosure, the deposition process comprises a cyclic deposition process, such as an atomic layer deposition (ALD) process or a cyclic chemical vapor deposition (CVD) process. The term “cyclic deposition process” can refer to the sequential introduction of precursor(s) and/or reactant(s) into a reaction chamber to deposit material, such as metal, on a substrate. Cyclic deposition includes processing techniques such as atomic layer deposition (ALD), cyclic chemical vapor deposition (cyclic CVD), and hybrid cyclic deposition processes that include an ALD component and a cyclic CVD component. The process may comprise a purge step between providing precursors or between providing a precursor and a reactant in the reaction chamber.

In the current disclosure, any two numbers of a variable can constitute a workable range of the variable, and any ranges indicated may include or exclude the endpoints.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

The process may comprise one or more cyclic phases. For example, pulsing of a metal alkoxide precursor and a second precursor may be repeated. Repeating the cyclic deposition steps may be used to control the thickness of the deposited material. In some embodiments, the process comprises one or more acyclic phases. In some embodiments, the deposition process comprises the continuous flow of at least one precursor. In some embodiments, a reactant may be continuously provided in the reaction chamber. In such an embodiment, the process comprises a continuous flow of a precursor or a reactant. In some embodiments, one or more of the precursors and/or reactants are provided in the reaction chamber continuously. A cyclic deposition process may usually be initiated with any of at least two precursors and/or reactants used in the process. Thus, in the current methods described herein, the first deposition cycle may be started by providing either a metal alkoxide precursor or a second precursor in the reaction chamber.

The term “atomic layer deposition” (ALD) can refer to a vapor deposition process in which deposition cycles, such as a plurality of consecutive deposition cycles, are conducted in a reaction chamber. The term “atomic layer deposition”, as used herein, is also meant to include processes designated by related terms, such as chemical vapor atomic layer deposition, when performed with alternating pulses of precursor(s)/reactant(s), and optional purge gas(es). Generally, for ALD processes, during each cycle, a precursor is introduced to a reaction chamber and is chemisorbed to a deposition surface (e.g., a substrate surface that may include a previously deposited material from a previous ALD cycle or other material), forming about a monolayer or sub-monolayer of material that does not readily react with additional precursor (i.e., a self-limiting reaction). Thereafter, in some cases, another precursor or a reactant may subsequently be introduced into the process chamber for use in converting the chemisorbed precursor to the desired material on the deposition surface. The another precursor or reactant can be capable of further reaction with the chemisorbed precursor. Purging steps may be utilized during one or more cycles, e.g., during each step of each cycle, to remove any excess precursor from the process chamber and/or remove any excess precursors, reactants and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a metal alkoxide precursor into the reaction chamber. In some embodiments, the cyclic deposition process comprises purging the reaction chamber after providing a second precursor into the reaction chamber. In some embodiments, the cyclic deposition process comprises purging the reaction chamber after providing each precursor into the reaction chamber.

CVD type processes typically involve gas phase reactions between two or more precursors and/or reactants. The precursor(s) and reactant(s) can be provided simultaneously to the reaction space or substrate, or in partially or completely separated pulses. The substrate and/or reaction space can be heated to promote the reaction between the gaseous precursor and/or reactants. In some embodiments, the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

As used herein, the term “purge” may refer to a procedure in which vapor phase precursors and/or vapor phase byproducts are removed from the substrate surface, for example, by evacuating the reaction chamber with a vacuum pump and/or by replacing the gas inside a reaction chamber with an inert or substantially inert gas, such as argon or nitrogen. Purging may be effected between two pulses of gases which react with each other. However, purging may be effected between two pulses of gases that do not react with each other. For example, a purge, or purging may be provided between pulses of two precursors or between a precursor and a reactant. Purging may avoid or at least reduce gas-phase interactions between two gases reacting with each other. It shall be understood that a purge can be effected either in time or in space, or both. For example, in the case of temporal purges, a purge step can be used e.g., in the temporal sequence of providing a first precursor to a reactor chamber, providing a purge gas to the reactor chamber, and providing a second precursor to the reactor chamber, wherein the substrate on which a layer is deposited does not move. For example, in the case of spatial purges, a purge step can take the following form: moving a substrate from a first location to which a first precursor is continually supplied, through a purge gas curtain, to a second location to which a second precursor is continually supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 1 s or 2 s. However, other purge times can be utilized if necessary, such as where highly conformal step coverage over extremely high aspect ratio structures or other structures with complex surface morphology is needed, or in specific reactor types, such as a batch reactor.

In some embodiments, a cyclic deposition process according to the current disclosure comprises a thermal deposition process. In thermal deposition, the chemical reactions may be promoted by increased temperature relevant to ambient temperature. Generally, temperature increase may provide the energy needed for the formation of metal-containing material in the absence of other external energy sources, such as plasma, radicals, or other forms of radiation. In some embodiments, a method according to the current disclosure is a plasma-enhanced deposition method, for example PEALD or PECVD.

The method according to the current disclosure comprise providing a substrate in a reaction chamber, providing a metal alkoxide precursor into the reaction chamber in a vapor phase, and providing a second precursor into the reaction chamber in a vapor phase to form metal-containing material on the substrate.

The method of depositing metal-containing material according to the current disclosure comprises providing a substrate in a reaction chamber. In other words, a substrate is brought into space where the deposition conditions can be controlled. The reaction chamber may be part of a cluster tool in which different processes are performed to form an integrated circuit. In some embodiments, the reaction chamber may be a flow-type reactor, such as a cross-flow reactor. In some embodiments, the reaction chamber may be a showerhead reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously. A reaction chamber according to the current disclosure may further be a deposition station in a multi-station chamber.

Further, in the method according to the current disclosure, a metal alkoxide precursor is provided into the reaction chamber in a vapor phase, and a second precursor is provided into the reaction chamber in a vapor phase to form a metal-containing material on the substrate.

In the method according to the current disclosure, the metal alkoxide precursor may be in vapor phase when it is in a reaction chamber. The metal alkoxide precursor may be partially gaseous or liquid, or even solid at some points in time prior to being provided in the reaction chamber. In other words, a metal alkoxide precursor may be solid, liquid or gaseous, for example, in a precursor vessel or other receptacle before delivery in a reaction chamber. Various methods and structures for bringing the precursor in to gas phase can be applied when delivery into the reaction chamber is performed. Such methods and structures may include, for example, heaters, vaporizers, gas flow or applying lowered pressure, or any combination thereof. Thus, the methods according to the current disclosure may comprise heating the metal alkoxide precursor prior to providing it to the reaction chamber.

Metal alkoxide compounds may decompose at relatively low temperatures in view of conventional cyclic deposition processes. For example, metal alkoxide compounds may begin to decompose at temperatures below 200° C. Some metal alkoxide compounds may begin to decompose at temperatures below 150° C. However, the inventors have discovered that the metal alkoxide compounds according to the current disclosure may be suitable, or even advantageous, for cyclic deposition processes at temperatures below about 140° C.

In some embodiments, the deposition of a metal-containing material according to the current disclosure is performed at a temperature below about 200° C., or below about 185° C., or below about 150° C. In some embodiments, the deposition is performed at a temperature from about 80° C. to about 150° C., for example from about 85° C. to about 130° C., such as at a temperature of about 80° C., about 90° C. about 110° C. or at about 130° C.

In some embodiments, a metal alkoxide precursor is heated to at least 30° C., to at least 50° C., or to at least 70° C., or to at least 90° C. or to at least 100° C. or to at least 110° C. before providing it to the reaction chamber. In some embodiments, a metal alkoxide precursor is heated to at least 120° C., or to at least 150° C. The heating may take place in a precursor vessel. In some embodiments, the metal alkoxide precursor is heated to at most 180° C., or to at most 160° C., or to at most 150° C., or to at most 120° C., or to at most 100° C., or to at most 80° C., or to at most 60° C. before providing it to the reaction chamber. The injector system of a vapor deposition assembly may be heated to improve the vapor-phase delivery of the metal alkoxide precursor to the reaction chamber.

In this disclosure, “gas” can include material that is a gas at normal temperature and pressure (NTP), a vaporized solid and/or a vaporized liquid, and can be constituted by a single gas or a mixture of gases, depending on the context. A metal alkoxide precursor may be provided to the reaction chamber in gas phase. A second precursor may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

In some embodiments, the metal-containing material comprises elemental metal. Thus, the deposited metal may at least partly have an oxidation state of 0. In some embodiments, substantially all or all of the metal is deposited as elemental metal. In some embodiments, the deposited metal comprises, consists essentially of, or consists of elemental copper. In some embodiments, the deposited metal comprises, consists essentially of, or consists of elemental bismuth. In some embodiments, a layer consisting essentially of, or consisting of, elemental metal is deposited. In some embodiments, the metal according to the current disclosure is deposited as a layer, and the layer comprises substantial amounts of other elements in addition to the metal. In such embodiments, the metal may be present as elemental metal. In some embodiments, the metal deposited according to the current disclosure is present as an alloy with another metal.

In some embodiments, the metal deposited according to the current disclosure is present at least partially in an oxidation state other than 0. In some embodiments, the metal deposited according to the current disclosure forms a compound with another element. In some embodiments, the metal-containing material deposited according to the current disclosure comprises a metal oxide. In some embodiments, the metal-containing material deposited according to the current disclosure comprises a metal nitride. In some embodiments, the metal-containing material deposited according to the current disclosure comprises a metal silicide. In some embodiments, the metal-containing material deposited according to the current disclosure comprises a metal germanide. In some embodiments, the metal-containing material deposited according to the current disclosure comprises a metal sulfide. In some embodiments, the metal-containing material deposited according to the current disclosure comprises a metal selenide. In some embodiments, the metal-containing material deposited according to the current disclosure comprises a metal phosphide. In some embodiments, the metal-containing material deposited according to the current disclosure comprises a metal boride. In some embodiments, the metal-containing material according to the current disclosure comprises two or more of the above materials. For example, the metal-containing material may comprise elemental metal and a metal carbide, or elemental metal and a metal nitride, or a combination of a metal carbide and a metal nitride.

The growth rate of metal-containing material may be, for example from about 0.05 to about 1.5 Å/cycle. The growth rate and the layer properties may depend on the temperature at which the deposition process is performed. In some embodiments, the growth rate may be about 0.1 Å/cycle, or about 0.2 Å/cycle, or about 0.5 Å/cycle, or about 1 Å/cycle. The growth rate may vary during a deposition process.

The deposition cycle, comprising providing metal alkoxide precursor into the reaction chamber (i.e., pulsing the metal alkoxide precursor) and providing the second precursor into the reaction chamber (i.e., pulsing the second precursor), as well as optional purging phases, may be repeated, for example about 100 times, about 125 times, about 200 times, about 250 times, about 350 times, about 500 times, about 750 times, about 1,000 times or about 1,500 times. In some embodiments, the deposition cycle may be repeated for at least about 100 times, about 250 times, at least about 350 times, at least about 500 times, at least about 750 times, at least about 1,000 times, at least about 1,500 times, at least about 2,000 times, or at least about 2,500 times.

The resistivity of a metal-containing material deposited as a layer depends on the material composition. Also, for a given material, such as elemental metal-containing material, the resistivity may depend on the process conditions, such as temperature and the growth rate of the layer. In embodiments, in which a metal-containing layer comprises mostly, or substantially only of elemental metal, the resistivity may be, for example, less than about 10 μΩcm, such as less than about 7 μΩcm, such as less than about 5 μΩcm, for example between 1 and 10 μΩcm, such as between 2 and 7 μΩcm.

In some embodiments, the metal-containing material comprises elemental metal, and less than 20 at. % carbon. In some embodiments, the metal-containing layer comprises elemental metal, and less than 15 at. % carbon. In some embodiments, the metal-containing layer comprises elemental metal, and less than 10 at. % carbon. In some embodiments, the metal-containing material comprises elemental metal, and less than 2 at. % oxygen. In some embodiments, the metal-containing material comprises elemental metal, and less than 1 at. % nitrogen.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. However, a reactant may also contribute to the resulting compound or element in certain embodiments.

As used herein, a “metal alkoxide precursor” includes a gas or a material that can become gaseous and that can be represented by a chemical formula that includes a metal alkoxide.

In some embodiments, the metal atom of the metal alkoxide precursor is a transition metal. In some embodiments, the metal atom of the metal alkoxide precursor is a late transition metal or a post-transition metal. In some embodiments, the metal atom is selected from a group consisting of nickel (Ni), copper (Cu), cobalt (Co), zinc (Zn), iron (Fe), aluminum (Al), bismuth (Bi), gallium (Ga), indium (In), thallium (Tl), tin (Sn), lead (Pb), molybdenum (Mo), tungsten (W), and niobium (Nb). In some embodiments, the metal atom comprises bismuth or copper.

In some embodiments, the metal alkoxide precursor comprises at least one alkoxide ligand. In some embodiments, the metal alkoxide precursor comprises at least two alkoxide ligands. In some embodiments, the metal alkoxide precursor comprises three alkoxide ligands.

In some embodiments, the metal alkoxide precursor is a metal aminoalkoxide precursor. In some embodiments, the metal alkoxide precursor comprises a ligand selected from 1-dimethylamino-2-propoxide (dmap), 1-dimethylamino-2-methyl-2-propoxide (dmamp), 1-ethylmethylamino-2-methyl-2-propoxide (emamp), 1-diethylamino-2-methyl-2-propoxide (deamp), 1-ethylmethylamino-2-methyl-2-butoxide (emamb), 1-dimethylamino-2-methyl-2-butoxide (dmamb), 1-dimethylamino-2-ethyl-2-butoxide (dmaeb), and 1-diethylamino-2-methyl-2-butoxide (deamb).

In some embodiments, the metal alkoxide precursor is selected from the group consisting of Ni(dmap)₂, Ni(dmamp)₂, Ni(emamp)₂, Ni(deamp)₂, Ni(emamb)₂, Ni(deamb)₂, Ni(dmaeb)₂, Co(dmap)₂, Co(dmamp)₂, Co(emamp)₂, Co(deamp)₂, Co(emamb)₂, Co(deamb)₂, Co(dmaeb)₂, Cu(dmap)₂, Cu(dmamp)₂, Cu(emamp)₂, Cu(deamp)₂, Cu(emamb)₂, Cu(deamb)₂, Cu(dmaeb)₂, Fe(dmap)₂, Fe(dmamp)₂, Fe(emamp)₂, Fe(deamp)₂, Fe(emamb)₂, Fe(deamb)₂, Fe(dmaeb)₂, Zn(dmap)₂, Zn(dmamp)₂, Zn(emamp)₂, Zn(deamp)₂, Zn(emamb)₂, Zn(deamb)₂, Zn(dmaeb)₂, Al(OⁱPr)₃, Al(OBu)₃, Al(OEt)₃, AlOⁱPr(Me)₂, Bi(OCMe₂ⁱPr)₃, Ga(O^{t}Bu)₃, GaCl₂(OCH₂CH₂NMe₂), Cu(OMe)₂, Cu(dmap)₂, Pb(dmamp)₂, Tl(OEt), Sn(O^{t}Bu)₄, Sn(OEt)₂and Zn(OⁱPr)₂. In some embodiments, the metal alkoxide precursor is selected from the group consisting of Al(OⁱPr)₃, Al(OBu)₃, Al(OEt)₃, AlOⁱPr(Me)₂, Bi(OCMe₂ⁱPr)₃, Ga(O^{t}Bu)₃, GaCl₂(OCH₂CH₂NMe₂), In(O^{t}Bu)₃ Cu(OMe)₂, Cu(dmap)₂, Pb(dmamp)₂, (C₅H₅)₂Ni, Tl(OEt), Sn(O^{t}Bu)₄, Sn(OEt)₂, Zn(OⁱPr)₂, Mo₂(OCMe₃)₆, W(OEt)₆, Nb₂(OEt)₁₀, Nb(OEt)₅, Mo₂(O₂CMe₃)₄ and Mo(thd)₃ (thd=2,2,6,6-tetramethylheptane-3,5-dionato).

In some embodiments the metal alkoxide precursor comprises, consists essentially of or consists of Bi(OCMe₂ⁱPr)₃. In some embodiments, the metal alkoxide precursor comprises, consists essentially of or consists of Cu(dmap)₂.

In some embodiments, a metal alkoxide precursor is provided in a mixture of two or more compounds. In a mixture, the other compounds in addition to the metal alkoxide precursor may be inert compounds or elements. In some embodiments, the metal alkoxide precursor is provided in a composition. Compositions suitable for use as composition can include a metal alkoxide compound and an effective amount of one or more stabilizing agents. Composition may be a solution or a gas in standard conditions. In some embodiments, a mixture of at least two metals may be deposited. In such embodiments, the metal alkoxide precursor may comprise two different metal-containing compounds, one or more of them being metal alkoxide compounds according to the current disclosure.

The metal-containing material is formed by providing a second precursor into the reaction chamber in a vapor phase. The conversion of a metal alkoxide precursor to the desired metal-containing material may take place at the substrate surface. In some embodiments, the conversion may take place at least partially in the gas phase. In some embodiments, the reactions between the metal alkoxide precursor and the second precursor take place substantially only on the surface of the substrate.

In some embodiments, the second precursor is a reducing agent. A reducing agent may reduce the metal of the metal alkoxide precursor into elemental metal. In some embodiments, the reducing agent is selected from a group consisting of forming gas (H₂+N₂), ammonia (NH₃), NH₃ plasma, a hydrazine (such as hydrazine (N₂H₄), tert-butyl hydrazine (tBuHNNH₂) and 1,1′-dimethylhydrazine (Me₂NNH₂)), molecular hydrogen (H₂), hydrogen atoms (H), a hydrogen plasma, hydrogen radicals, hydrogen excited species, an alcohol (such as MeOH), an aldehyde, a carboxylic acid (such as formic acid), a borane (such as borane (BH₃)), diborane (B₂H₆), borane dimethylamine (BH₃(NHMe₂)), an amine (such as tert-butylamine (tBu)NH₂, diethylamine (Et₂NH)), a silane (such as silane (SiH₄), disilane (Si₂H₆), trisilane (Si₃H₈)) and germane (such as germane (GeH₄) and digermane (Ge₂H₆)). Many of the reducing agents listed above may work only with certain metal alkoxide precursors. Thus, the listed compounds may not function as general reducing agents.

In some embodiments, the second precursor is an oxygen precursor, a nitrogen precursor, a carbon precursor, a silicon precursor, sulfur precursor, selenium precursor, phosphorus precursor or a boron precursor.

In some embodiments, the second precursor comprises a borane compound. In some embodiments, the second precursor is selected from the group consisting of pinacolborane, bis-pinacolatoboron, 9-BBN, Borane morpholine, catechol borane, 2-picoline borane, borane pyridine adduct, decaborane, 1,4-bis(pinacolatoboron)-1,4-dihydropyrazine, H₃B*NEt₃, H₃B*NHMe₂, H₃B*SMe₂, BN(Et)ⁱPr₂ and BH₃*THF. In some embodiments, the second precursor comprises an alkoxy borane compound. In some embodiments, the second precursor comprises, consists essentially of or consists of pinacolborane.

Similarly to the metal alkoxide precursor, a second precursor may be heated before providing it to the reaction chamber. The temperature to which the second precursor is heated depends on the properties of the second precursor. As is understood by those skilled in the art, the vaporization temperatures of the metal alkoxide precursor and the second precursor may need to be compatible.

In some embodiments, a second precursor is heated to at least 20° C., to at least 25° C., to at least 30° C., to at least 50° C., or to at least 70° C., or to at least 90° C. or to at least 100° C. or to at least 110° C. before providing it to the reaction chamber. The heating may take place in a precursor vessel. In some embodiments, the second precursor is heated to at most 120° C., or to at most 100° C., or to at most 80° C., or to at most 60° C. before providing it to the reaction chamber. The injector system of a vapor deposition assembly may be heated to improve the vapor-phase delivery of the second precursor to the reaction chamber.

In one aspect of the invention, a metal-containing layer produced by a cyclic deposition process is disclosed. The process comprises providing a substrate into a reaction chamber; providing a metal alkoxide precursor into the reaction chamber in vapor phase; and providing a second precursor into the reaction chamber in vapor phase to form a material on the substrate. In the process, the second precursor comprises a borane compound.

In one aspect of the invention, a semiconductor structure comprising a metal-containing layer deposited by a cyclic deposition process is disclosed. The process comprises providing a substrate into a reaction chamber; providing a metal alkoxide precursor into the reaction chamber in vapor phase; and providing a second precursor into the reaction chamber in vapor phase to form a material on the substrate. In the process, the second precursor comprises a borane compound.

In one aspect of the invention a semiconductor device comprising a metal-containing layer deposited by a cyclic deposition process is disclosed. The process comprises providing a substrate into a reaction chamber; providing a metal alkoxide precursor into the reaction chamber in vapor phase; and providing a second precursor into the reaction chamber in vapor phase to form material on the substrate. In the process, the second precursor comprises a borane compound.

In one aspect of the invention, a deposition assembly for depositing metal-containing material on a substrate is disclosed. The deposition assembly comprises one or more reaction chambers constructed and arranged to hold the substrate; a precursor injector system constructed and arranged to provide a metal alkoxide precursor and a second precursor into the reaction chamber in a vapor phase. The second precursor comprises a borane compound. The deposition assembly further comprises a precursor vessel constructed and arranged to contain a metal alkoxide precursor; and the assembly is constructed and arranged to provide the metal alkoxide precursor and the second precursor via the precursor injector system to the reaction chamber to deposit metal-containing material on the substrate.

In one aspect of the invention, a vessel comprising a chemical precursor is disclosed. The vessel comprises bismuth alkoxide, wherein the vessel is configured to supply a vapor of the chemical precursor to a semiconductor processing apparatus chamber.

In one aspect of the invention, a metal-containing film deposition product is disclosed. The product comprises: a metal-containing chemical precursor comprising a metal alkoxide; a second precursor comprising alkoxy borane; a first vessel comprising the metal-containing chemical precursor; and a second vessel comprising the second precursor, wherein the metal-containing chemical precursor is provided in the first vessel and the second precursor is provided in the second vessel, wherein the first and second vessels are configured to couple to a semiconductor apparatus via a reactant delivery system.

The vapor deposition assembly for depositing metal-containing material on a substrate comprises one or more reaction chambers constructed and arranged to hold the substrate and a precursor injector system constructed and arranged to provide a metal alkoxide precursor according to the current disclosure into the reaction chamber in a vapor phase. The vapor deposition assembly further comprises a reactant vessel constructed and arranged to contain a composition according to the current disclosure and the assembly is constructed and arranged to provide a composition according to the current disclosure via the precursor injector system to the reaction chamber to deposit metal-containing material on the substrate.

In some embodiments, the vapor deposition assembly may additionally include control processors and software programmed and/or configured to operate the reaction chamber to perform an ALD process. In some embodiments, the vapor deposition assembly may additionally include control processors and software configured to operate the reaction chamber to perform a CVD process.

In one embodiment of the current disclosure, a selective deposition method is disclosed. The method comprises providing a substrate into a reaction chamber; providing a metal alkoxide precursor into the reaction chamber in vapor phase; and providing a second precursor into the reaction chamber in vapor phase to form a material on the substrate. In the method, the second precursor comprises a borane compound. The substrate comprises a first surface and a second surface. The deposited material is formed more on the first surface compared to the second surface. In other words, the first surface is a growth surface on which the deposited layer grows and the second surface is a non-growth surface on which the deposited layer does not grow, or grows only minimally.

In some embodiments, the first surface is selected from the group consisting of silicon, titanium nitride and alumina. In some embodiments, the first surface is selected from the group consisting of Si, SiO₂, SiN, SiC, SiOC, Ge, SiGe, TiN, TiCx, TaN, TaC, MoN, MoC, WN, WC, NbN, NbC, VN, VC, Al₂O₃, AlN, Ga₂O₃, GaN, In₂O₃, IGZO, TiO₂, ZrO₂, HfO₂, V₂O₅, VO₂, Nb₂O₅, Ta₂O₅, MoO₃, MoO₂, WO₃, MoS₂, WS₂, Sc₂O₃, Y₂O₃, La₂O₃, Ce₂O₃ and CeO₂. In some embodiments, the second surface is selected from the group consisting of cobalt and platinum. In some embodiments, the second surface is selected from the group consisting of Ni, Pd, Pt, Co, Rh, Ir, Ru, Re, Cr, Mo and W.

In some embodiments, the selective deposition can be obtained by selectively forming an inhibitor layer on the first surface. The inhibitor layer is formed on the substrate and it inhibits the growth of the deposited material on the surface. In some embodiments, the second precursor can be used as the inhibitor layer. In some embodiments, the second precursor comprises pinacolborane. In some embodiments, the deposited material is selected from the group consisting of Ni, Cu, Co, Zn, Fe, Al, Bi, Ga, In, Tl, Sn, Mo, Nb and Pb. In some embodiments, the deposited material is selected from Cu and Bi.

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

The particular implementations shown and described are illustrative of the invention and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

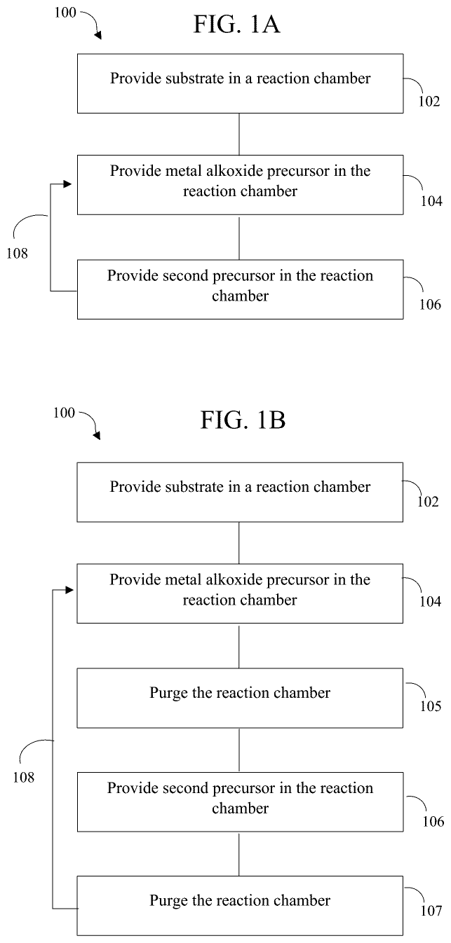

FIGS. 1A and 1B illustrate a block diagram of an embodiment of a method 100 of depositing metal-containing material on a substrate. In the first phase 102, a substrate is provided into a reaction chamber. A substrate according to the current disclosure may comprise, for example, an oxide, such as silicon oxide (for example thermal silicon oxide or native silicon oxide). A substrate may comprise a nitride, such as silicon nitride or titanium nitride, a metal, such as copper, cobalt or tungsten, or a chalcogenide material, such as molybdenum sulfide. The metal-containing material according to the current disclosure may be deposited on said surfaces.

The reaction chamber can form part of an atomic layer deposition (ALD) assembly. The reaction chamber can form part of a chemical vapor deposition (CVD) assembly. The assembly may be a single wafer reactor. Alternatively, the reactor may be a batch reactor. The assembly may comprise one or more multi-station deposition chambers. Various phases of method 100 can be performed within a single reaction chamber or they can be performed in multiple reaction chambers, such as reaction chambers of a cluster tool. In some embodiments, the method 100 is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The metal-containing material according to the current disclosure may be deposited in a cross-flow reaction chamber. The metal-containing material according to the current disclosure may be deposited in a showerhead reaction chamber.

Metal alkoxide precursor is provided in the reaction chamber containing the substrate 104. Without limiting the current disclosure to any specific theory, metal alkoxide precursor may chemisorb on the substrate during providing metal alkoxide precursor into the reaction chamber. The duration of providing metal alkoxide precursor into the reaction chamber (metal alkoxide precursor pulse time) may be, for example, 0.5 seconds, 1 second, 1.5 seconds, 2 seconds, 3 seconds, 4 seconds or 5 seconds.

In the second deposition phase 106 of a method 100, a second precursor is provided in the reaction chamber. In some embodiments, the second precursor comprises a reducing agent for depositing elemental metal on the substrate. In some embodiments, the second precursor comprises an oxygen precursor for depositing metal oxide on the substrate. In some embodiments, the second precursor comprises a nitrogen precursor for depositing metal nitride on the substrate. In some embodiments, the second precursor comprises a carbon precursor for depositing metal carbide on the substrate. In some embodiments, the second precursor comprises a silicon precursor for depositing metal silicide on the substrate. In some embodiments, the second precursor comprises a chalcogen precursor (such as sulfur or selenium precursor) for depositing metal chalcogenide, such as a metal sulfide or a metal selenide, on the substrate. In some embodiments, the second precursor comprises a phosphorus precursor for depositing metal phosphide on the substrate.

Phases of providing a metal alkoxide precursor 104 and providing a second precursor 106 may be performed in any order. The phases of providing a metal alkoxide precursor 104 and providing a second precursor 106 may constitute a deposition cycle, resulting in the deposition of metal-containing material. In some embodiments, the two phases of metal-containing material deposition, namely providing the metal alkoxide precursor and the second precursor in the reaction chamber (104 and 106), may be repeated (loop 108). Such embodiments contain several deposition cycles. The thickness of the deposited metal-containing material may be regulated by adjusting the number of deposition cycles. The deposition cycle (loop 108) may be repeated until a desired metal-containing material thickness is achieved. For example, about 50, 100, 200, 300, 400, 500, 700, 800, 1,000, 1,200, 1,500, 2,000, 2,400 or 3,000 deposition cycles may be performed. The cyclical deposition may result in the formation of a metal-containing layer. The layer may be substantially continuous or continuous.

In some embodiments, the cyclic deposition process comprises providing the metal precursor and the second precursor alternately and sequentially in the reaction chamber. In some embodiments, the reaction chamber is purged between precursors, 105, 107, as depicted in FIG. 1B. In such embodiments, a deposition cycle may be considered to contain phases 104, 105, 106 and 107. As above, a deposition cycle may be repeated 108 a number of times to achieve desired metal-containing material thickness.

Metal alkoxide precursor and second precursor may be provided in the reaction chamber in separate steps (104 and 106). FIG. 1B illustrates an embodiment according to the current disclosure, where steps 104 and 106 are separate by purge steps 105 and 107. In such embodiments, a deposition cycle comprises one or more purge steps 103, 105. During purge steps, precursor and/or reactant can be temporally separated from each other by inert gases, such as argon (Ar), nitrogen (N2) or helium (He) and/or a vacuum pressure. The separation of metal alkoxide precursor and second precursor may alternatively be spatial.

Purging the reaction chamber 103, 105 may prevent or mitigate gas-phase reactions between a metal alkoxide precursor and a second precursor, and enable possible self-saturating surface reactions. Surplus chemicals and reaction byproducts, if any, may be removed from the substrate surface, such as by purging the reaction chamber or by moving the substrate, before the substrate is contacted with the next reactive chemical. In some embodiments, however, the substrate may be moved to separately contact a metal alkoxide precursor and a second precursor. Because in some embodiments, the reactions may self-saturate, strict temperature control of the substrates and precise dosage control of the precursors may not be required. However, the substrate temperature is preferably such that an incident gas species does not condense into monolayers or multimonolayers nor thermally decompose on the surface.

When performing the method 100, metal-containing material is deposited onto the substrate. The deposition process may be a cyclical deposition process, and may include cyclical CVD, ALD, or a hybrid cyclical CVD/ALD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of a metal alkoxide precursor and a second precursor. Such a process may be referred to as cyclical CVD. In some embodiments, a cyclical CVD process may comprise the introduction of two or more precursors into the reaction chamber, wherein there may be a time period of overlap between the two or more precursors in the reaction chamber resulting in both an ALD component of the deposition and a CVD component of the deposition. This is referred to as a hybrid process. In accordance with further embodiments, a cyclical deposition process may comprise the continuous flow of one reactant or precursor and the periodic pulsing of the other chemical component into the reaction chamber. The temperature and/or pressure within a reaction chamber during step 104 can be the same or similar to any of the pressures and temperatures noted above in connection with step 102.

In some embodiments, the metal alkoxide precursor is brought into contact with a substrate surface 104, excess metal alkoxide precursor is partially or substantially completely removed by an inert gas or vacuum 105, and second precursor is brought into contact with the substrate surface comprising metal alkoxide precursor. Metal alkoxide precursor may be brought in to contact with the substrate surface in one or more pulses 104. In other words, pulsing of the metal alkoxide precursor 104 may be repeated. The metal alkoxide precursor on the substrate surface may react with the second precursor to form metal-containing material on the substrate surface. Also, pulsing of the second precursor 106 may be repeated. In some embodiments, second precursor may be provided in the reaction chamber first 106. Thereafter, the reaction chamber may be purged 105 and metal alkoxide precursor provided in the reaction chamber in one or more pulses 104.

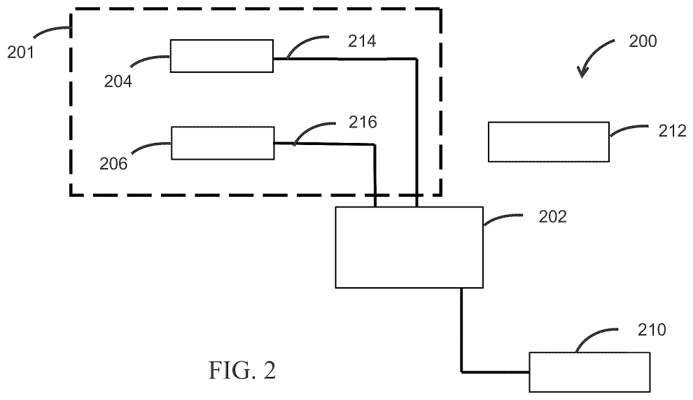

FIG. 2 illustrates a deposition assembly 200 according to the current disclosure in a schematic manner. Deposition assembly 200 can be used to perform a method as described herein and/or to form a structure or a device, or a portion thereof as described herein.

In the illustrated embodiment, deposition assembly 200 includes one or more reaction chambers 202, a precursor injector system 201, a metal alkoxide precursor vessel 204, a second precursor vessel 206, an exhaust source 210, and a controller 212. The deposition assembly 200 may comprise one or more additional gas sources (not shown), such as an inert gas source, a carrier gas source and/or a purge gas source.

Reaction chamber 202 can include any suitable reaction chamber, such as an ALD or CVD reaction chamber as described herein.

The metal alkoxide precursor vessel 204 can include a vessel and one or more metal alkoxide precursors as described herein-alone or mixed with one or more carrier (e.g., inert) gases. A second precursor vessel 206 can include a vessel and a second precursor as described herein-alone or mixed with one or more carrier gases. Although illustrated with two source vessels 204, 206, deposition assembly 200 can include any suitable number of source vessels. Source vessels 204, 206 can be coupled to reaction chamber 202 via lines 214, 216, which can each include flow controllers, valves, heaters, and the like. In some embodiments, the metal alkoxide precursor in the metal alkoxide precursor vessel 204 and the second precursor in the second precursor vessel 206 may be heated. In some embodiments, a vessel is heated so that a precursor or a reactant reaches a temperature between, for example, about 20° C. and about 200° C., depending on the properties of the chemical in question.

Exhaust source 210 can include one or more vacuum pumps.

Controller 212 includes electronic circuitry and software to selectively operate valves, manifolds, heaters, pumps and other components included in the deposition assembly 200. Such circuitry and components operate to introduce precursors, reactants and purge gases from the respective sources. Controller 212 can control timing of gas pulse sequences, temperature of the substrate and/or reaction chamber 202, pressure within the reaction chamber 202, and various other operations to provide proper operation of the deposition assembly 200. Controller 212 can include control software to electrically or pneumatically control valves to control flow of precursors, reactants and purge gases into and out of the reaction chamber 202. Controller 212 can include modules such as a software or hardware component, which performs certain tasks. A module may be configured to reside on the addressable storage medium of the control system and be configured to execute one or more processes.

Other configurations of deposition assembly 200 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 202. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 200, substrates, such as semiconductor wafers (not illustrated), are transferred from, e.g., a substrate handling system to reaction chamber 202. Once substrate(s) are transferred to reaction chamber 202, one or more gases from gas sources, such as precursors, reactants, carrier gases, and/or purge gases, are introduced into reaction chamber 202.

In some embodiments, the metal alkoxide precursor is supplied in pulses, the second precursor is supplied in pulses and the reaction chamber is purged between consecutive pulses of a metal alkoxide precursor and a second precursor.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of deposition a material on a substrate by cyclic deposition process, the method comprising:
providing a substrate into a reaction chamber;
providing a metal alkoxide precursor into the reaction chamber in vapor phase; and
providing a second precursor into the reaction chamber in vapor phase to form a material on the substrate;
wherein the second precursor comprises a borane compound.

2. The method according to claim 1, wherein the metal alkoxide precursor comprises at least one alkoxide ligand.

3. The method according to claim 1, wherein the metal alkoxide precursor comprises at least two alkoxide ligands.

4. The method according to claim 1, wherein the metal alkoxide precursor comprises three alkoxide ligands.

5. The method according to claim 1, wherein the metal alkoxide precursor is a metal aminoalkoxide precursor.

6. The method according to claim 1, wherein the metal alkoxide precursor comprises a ligand selected from the group consisting of dmap, dmamp, emamp, deamp, emamb, deamb, dmamb and dmaeb.

7. The method according to claim 1, wherein the metal atom of the metal alkoxide precursor is selected from the group consisting of late transition metals and post-transition metals.

8. The method according to claim 1, wherein the metal atom is selected from the group consisting of Ni, Cu, Co, Zn, Fe, Al, Bi, Ga, In, Tl, Sn, Mo, W, Nb and Pb.

9. The method according to claim 1, wherein the metal atom comprises Bi or Cu.

10. The method according to claim 1, wherein the metal alkoxide precursor is selected from the group consisting of Ni(dmap)₂, Ni(dmamp)₂, Ni(emamp)₂, Ni(deamp)₂, Ni(emamb)₂, Ni(deamb)₂, Ni(dmaeb)₂, Co(dmap)₂, Co(dmamp)₂, Co(emamp)₂, Co(deamp)₂, Co(emamb)₂, Co(deamb)₂, Co(dmaeb)₂, Cu(dmap)₂, Cu(dmamp)₂, Cu(emamp)₂, Cu(deamp)₂, Cu(emamb)₂, Cu(deamb)₂, Cu(dmaeb)₂, Fe(dmap)₂, Fe(dmamp)₂, Fe(emamp)₂, Fe(deamp)₂, Fe(emamb)₂, Fe(deamb)₂, Fe(dmaeb)₂, Zn(dmap)₂, Zn(dmamp)₂, Zn(emamp)₂, Zn(deamp)₂, Zn(emamb)₂, Zn(deamb)₂, Zn(dmaeb)₂, Al(OⁱPr)₃, Al(OBu)₃, Al(OEt)₃, AlOⁱPr(Me)₂, Bi(OCMe₂ⁱPr)₃, Ga(O^{t}Bu)₃, GaCl₂(OCH₂CH₂NMe₂), Cu(OMe)₂, Cu(dmap)₂, Pb(dmamp)₂, Tl(OEt), Sn(O^{t}Bu)₄, Sn(OEt)₂, Zn(OⁱPr)₂, Mo₂(OCMe₃)₆, Nb₂(OEt)₁₀, Nb(OEt)₅, Mo₂(O₂CMe₃)₄ and Mo(thd)₃.

11. The method according to claim 1, wherein the metal alkoxide precursor is selected from the group consisting of Al(OⁱPr)₃, Al(OBu)₃, Al(OEt)₃, AlOⁱPr(Me)₂, Bi(OCMe₂ⁱPr)₃, Ga(O^{t}Bu)₃, GaCl₂(OCH₂CH₂NMe₂), In(O^{t}Bu)₃ Cu(OMe)₂, Cu(dmap)₂, Pb(dmamp)₂, Tl(OEt), Sn(O^{t}Bu)₄, Sn(OEt)₂ and Zn(OⁱPr)₂.

12. The method according to claim 1, wherein the metal alkoxide precursor is selected from the group consisting of Bi(OCMe₂ⁱPr)₃ and Cu(dmap)₂.

13. The method of claim 1, wherein the second precursor is a reducing agent.

14. The method according to claim 1, wherein the second precursor is selected from the group consisting of pinacolborane, bis-pinacolatoboron, 9-BBN, Borane morpholine, catechol borane, 2-picoline borane, borane pyridine adduct, 1,4-bis(pinacolatoboron)-1,4-dihydropyrazine, decaborane and BN(Et)ⁱPr₂.

15. The method according to claim 1, wherein the second precursor comprises an alkoxy borane compound.

16. The method according to claim 1, wherein the second precursor comprises pinacolborane.

17. The method according to claim 1, wherein the metal-containing material comprises elemental metal.

18. A method for selectively depositing a material on a substrate by cyclic deposition process, the method comprising:
providing a substrate into a reaction chamber, wherein the substrate comprises a first surface and a second surface;
providing a metal alkoxide precursor into the reaction chamber in vapor phase; and
providing a second precursor into the reaction chamber in vapor phase to form a material on the substrate;
wherein the second precursor comprises a borane compound, and
wherein the deposited material is formed more on the first surface compared to the second surface.

19. The method according to claim 18, wherein the first surface is selected from the group consisting of silicon, titanium nitride and alumina.

20. The method according to claim 18, wherein the second surface is selected from the group consisting of cobalt and platinum.

21-26. (canceled)
